(19) United States
(12) Patent Application Publication
(10) Pub. No.: US 2025/0386555 A1
(43) Pub. Date: Dec. 18, 2025

(54) SEMICONDUCTOR DEVICES WITH RECRYSTALIZED SOURCE/DRAIN REGION AND METHODS OF FABRICATION THEREOF

(71) Applicant: TAIWAN SEMICONDUCTOR MANUFACTURING COMPANY, LTD., Hsinchu (TW)

(72) Inventors: Wen-Yen CHEN, Hsinchu (TW); Tsai-Yu HUANG, Taoyuan (TW); Chia-Cheng CHEN, Hsinchu (TW); Chien-Hao CHEN, Ilan (TW)

(21) Appl. No.: 18/934,368

(22) Filed: Nov. 1, 2024

Related U.S. Application Data
(60) Provisional application No. 63/660,639, filed on Jun. 17, 2024.

(51) Int. Cl. H01L 29/78; H01L 21/02; H01L 29/06; H01L 29/08; H01L 29/423; H01L 29/66; H01L 29/775; H01L 29/786

(52) U.S. Cl. CPC H10D 30/796; H01L 21/02532; H01L 21/02675; H10D 30/014; H10D 30/43; H10D 30/6735; H10D 30/6757; H10D 62/121; H10D 62/151; H10D 64/017; H10D 64/018

(57) ABSTRACT

Embodiments with present disclosure provide a method for forming a semiconductor device including recrystallized source/drain regions. The recrystallized source/drain regions may be formed by a high temperature treatment after epitaxial process.

### CROSS-REFERENCE TO RELATED APPLICATIONS

This application claims priority to the U.S. Provisional Patent Application Ser. No. 63/660,639 filed Jun. 17, 2024, which is incorporated by reference in its entirety.

### BACKGROUND

The semiconductor industry has experienced continuous rapid growth due to constant improvements in the integration density of various electronic components. For the most part, this improvement in integration density has come from repeated reductions in minimum feature size, allowing more components to be integrated into a given chip area. As minimum feature size reduces, defects in epitaxial crystalline materials may include undesirable effects. Therefore, there is a need to remove defects in epitaxial material.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart of a method for manufacturing of a semiconductor substrate according to embodiments of the present disclosure.

FIGS. 2A, 2B, 2C, 2D, 2E, 2F, 2G, 2H, 2I, 2J, and 2K schematically illustrate various stages of manufacturing a semiconductor device according to embodiments of the present disclosure.

FIG. 3A is a phase diagram of a two-element semiconductor material.

FIG. 3B schematically illustrates a re-crystallization of an epitaxial material according to embodiments of the present disclosure.

FIGS. 4A-4B schematically illustrate a semiconductor device according to one embodiment of the present disclosure.

FIGS. 5A-5B schematically illustrate a semiconductor device according to one embodiment of the present disclosure.

FIG. 6 schematically illustrates a semiconductor device according to one embodiment of the present disclosure.

FIG. 7 is a flow chart of a method for manufacturing of a semiconductor substrate according to embodiments of the present disclosure.

FIGS. 8A-8B schematically illustrate various stages of manufacturing a semiconductor device according to embodiments of the present disclosure.

FIG. 9 is a flow chart of a method for manufacturing of a semiconductor substrate according to embodiments of the present disclosure.

FIGS. 10A-10B schematically illustrate various stages of manufacturing a semiconductor device according to embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The foregoing broadly outlines some aspects of embodiments described in this disclosure. While some embodiments described herein are described in the context of nanosheet channel FETs, implementations of some aspects of the present disclosure may be used in other processes and/or in other devices, such as planar FETs, Fin-FETs, Horizontal Gate All Around (HGAA) FETs, Vertical Gate All Around (VGAA) FETs, and other suitable devices. A person having ordinary skill in the art will readily understand other modifications that may be made are contemplated within the scope of this disclosure. In addition, although method embodiments may be described in a particular order, various other method embodiments may be performed in any logical order and may include fewer or more steps than what is described herein. In the present disclosure, a source/drain region refers to a source and/or a drain. A source and a drain are interchangeably used.

The fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process.

Embodiments of the present disclosure relate to a semiconductor device including epitaxial source/drain regions with improved crystalline structure. Particularly, an anneal process is performed after source-drain epitaxy to create fully amorphous source-drain material. Following the anneal process, liquid-phase-epitaxy-regrowth (LPER) is induced to re-crystalize the source-drain regions, resulting in uniform crystalline in the source/drain regions. In addition to strain recovery, LPER also boosts dopant activation to improve difference between on-state current Iₒₙ and off-state current I_{off}, thus, improving device performance and lower leakage power. The LPER process also reduces resistance of source-drain material of nanosheet devices. The anneal process, which melts the source/drain region, improves the electrical performance in channels between source/drain regions. The anneal process may be performed before or after formation of contact etch stop layer (CESL) and interlayer deposition (IDL) layer.

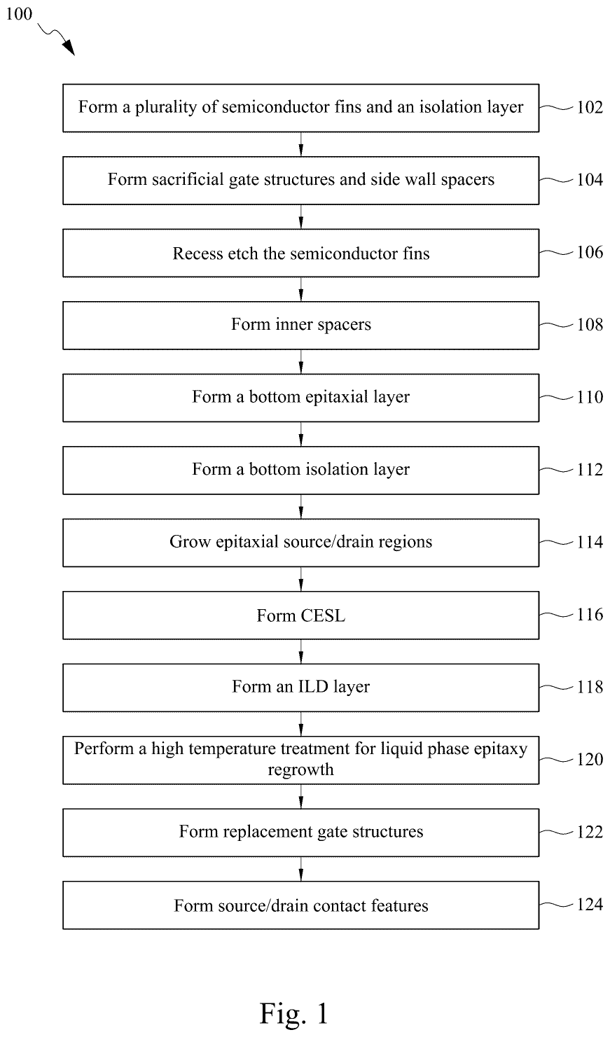

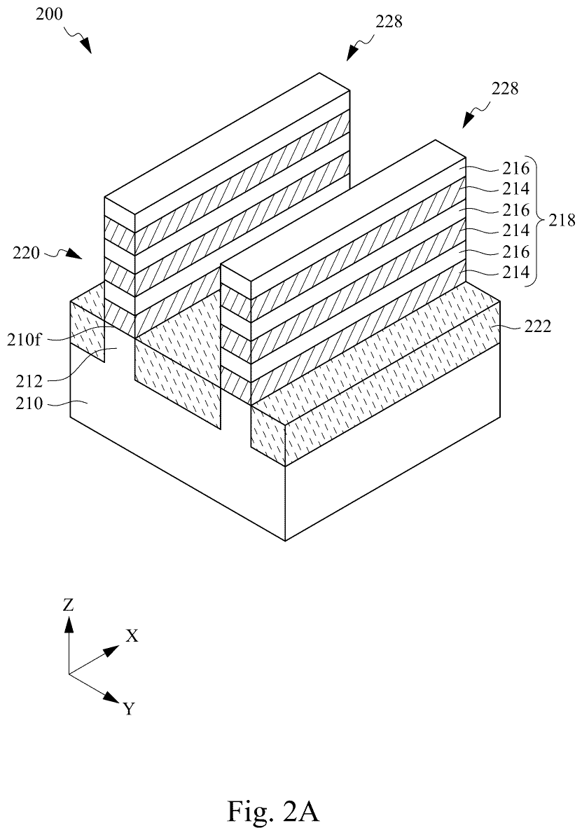

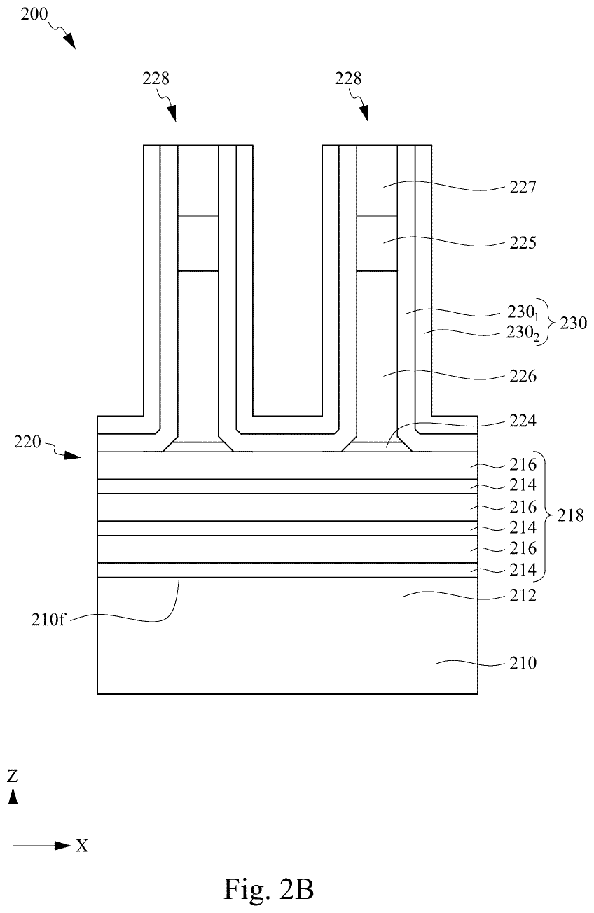

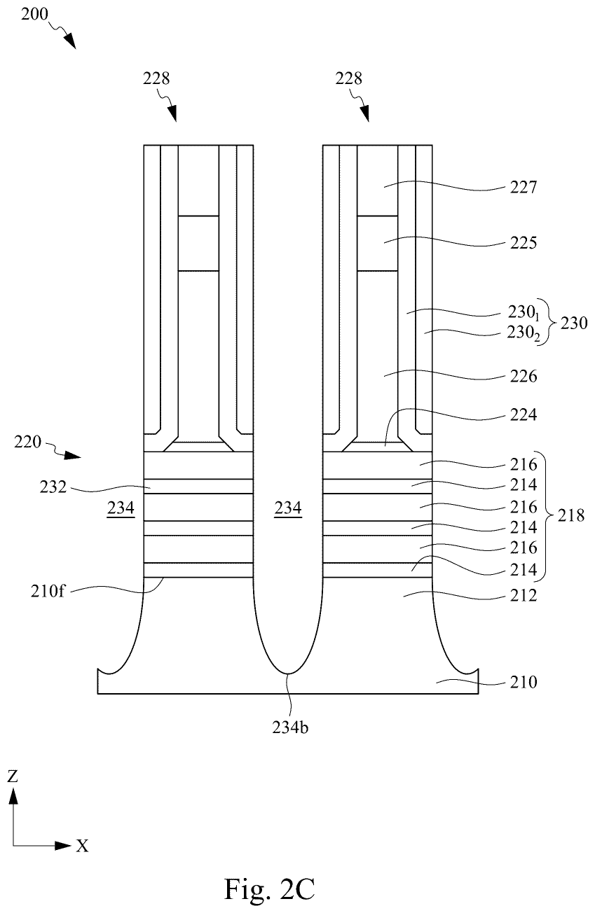

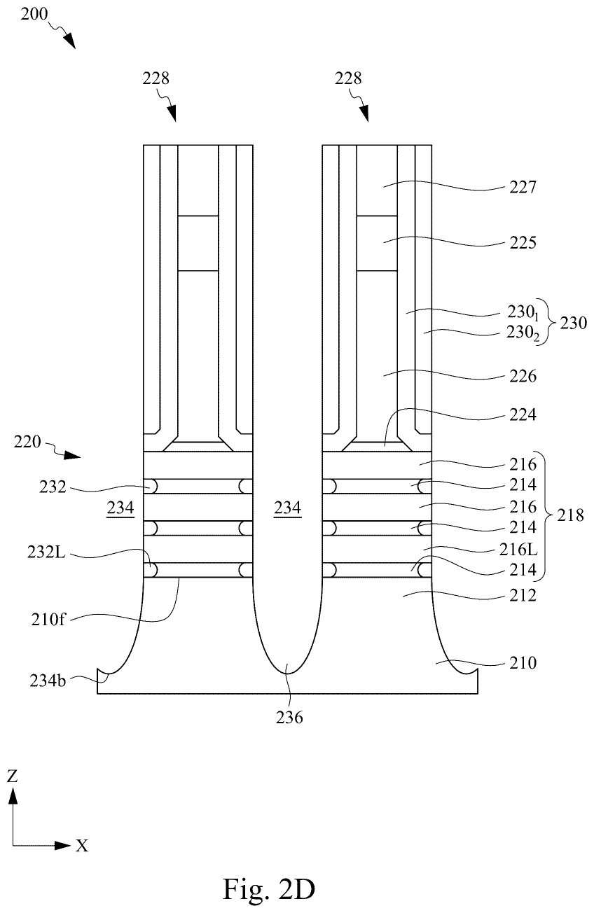

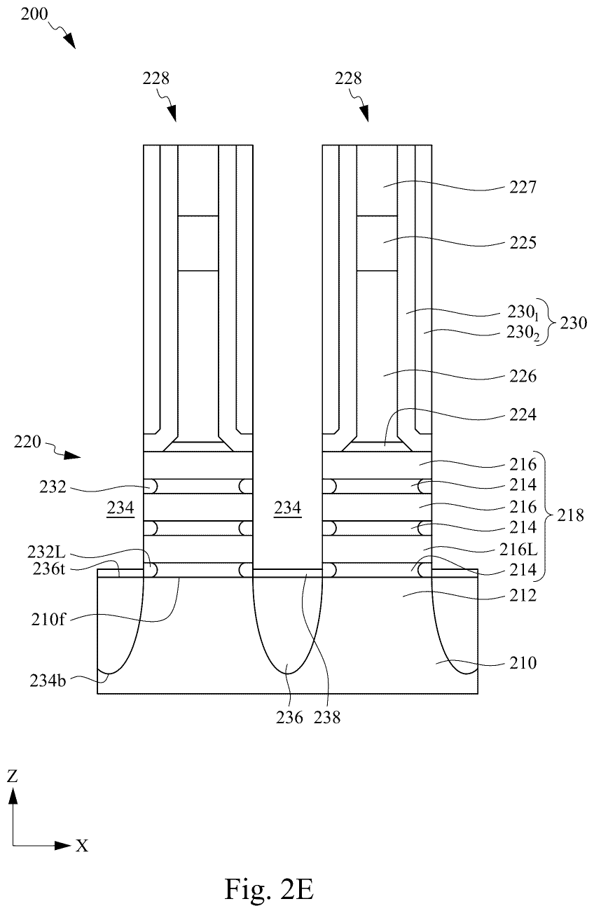

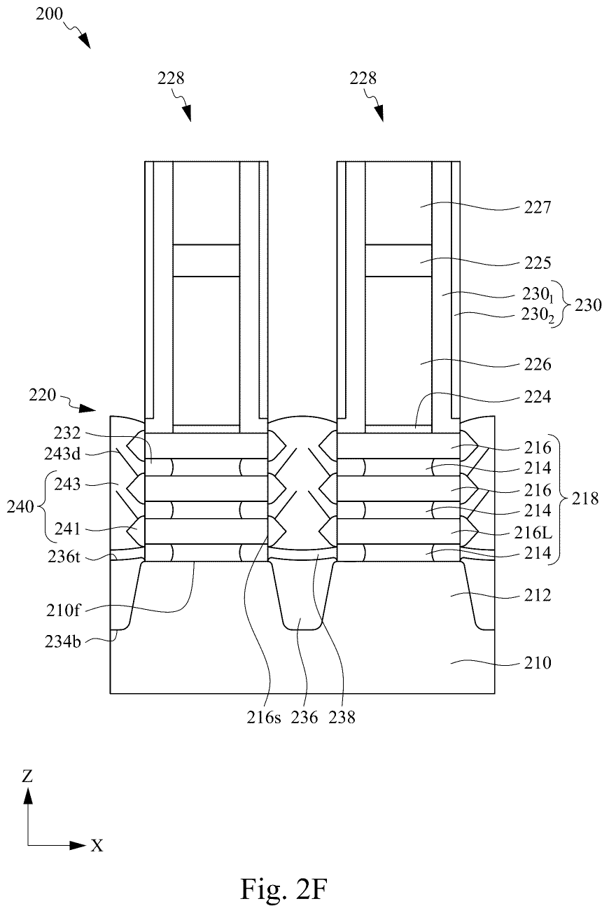

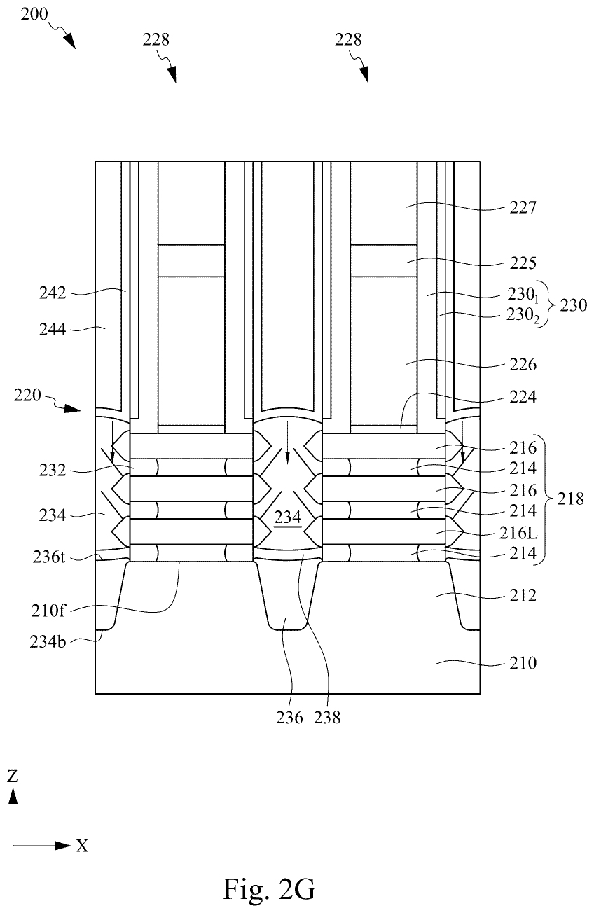

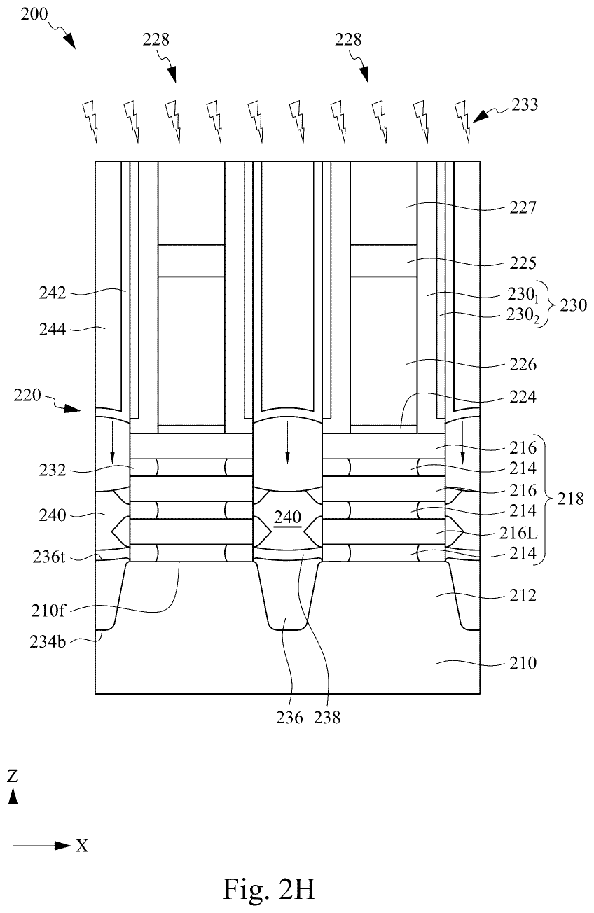

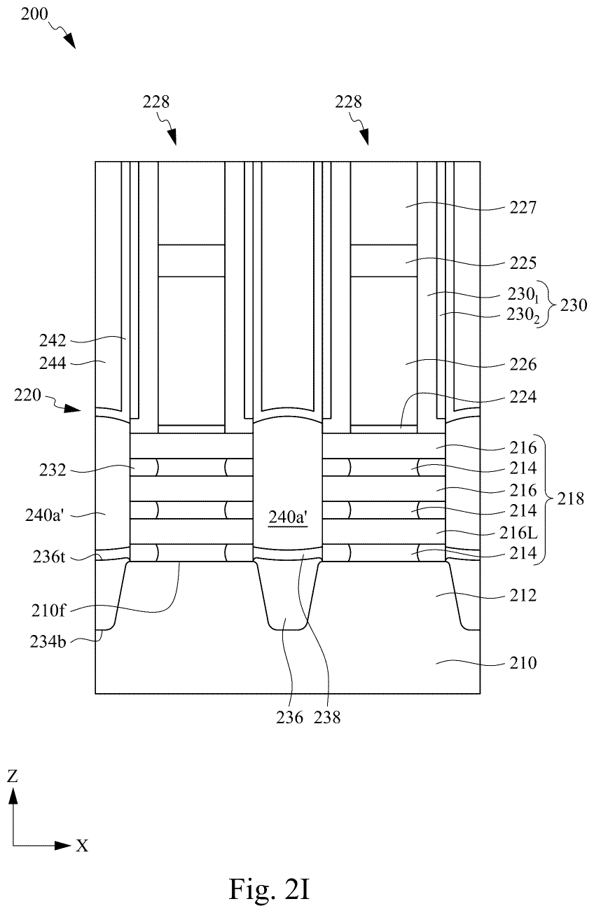

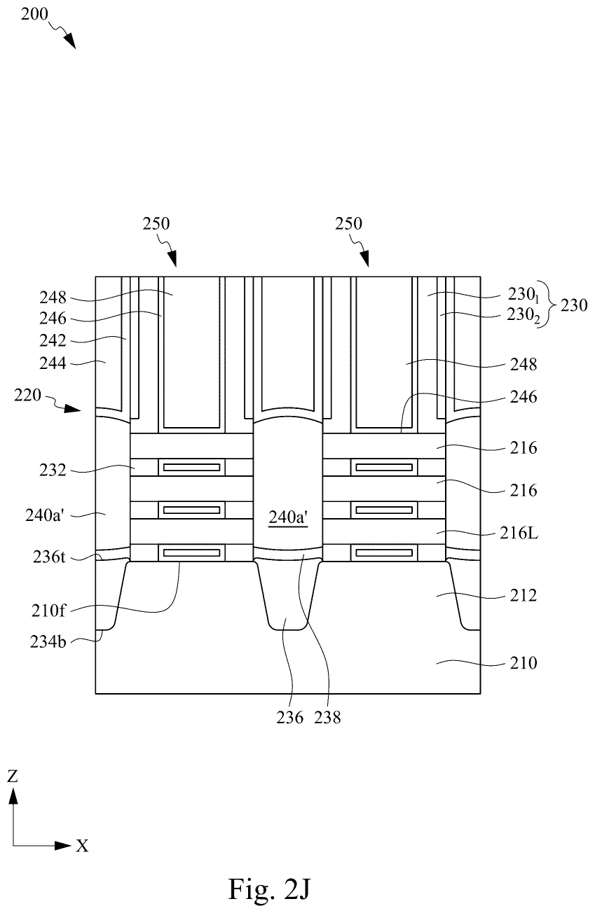

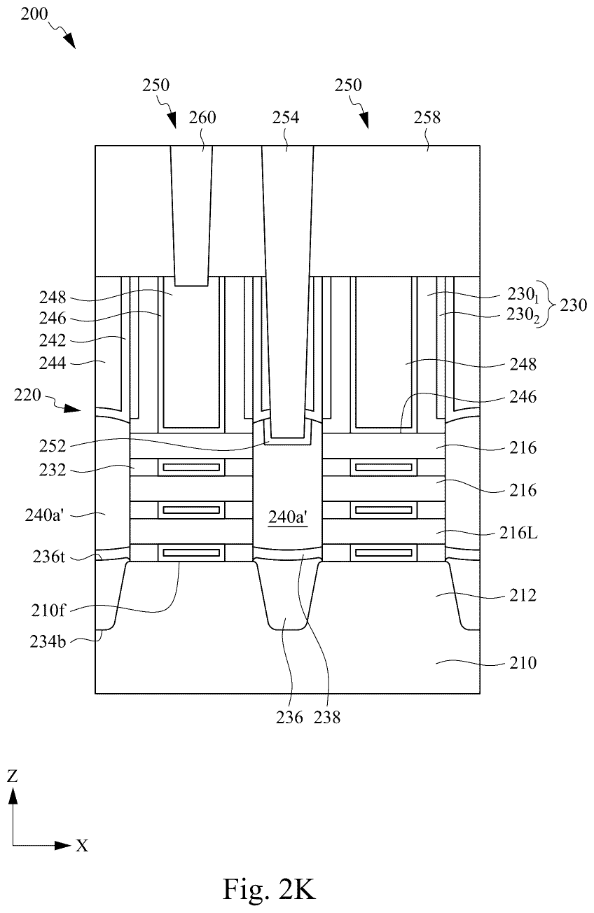

FIG. 1 is a flow chart of a method 100 for manufacturing of a semiconductor device according to embodiments of the present disclosure. FIGS. 2A-2J schematically illustrate various stages of manufacturing a semiconductor device 200 according to embodiments of the present disclosure.

The method 100 begins at operation 102 where a plurality of fin structures 220 are formed over a substrate 210, as shown in FIG. 2A. FIG. 2A is a schematic perspective view of the semiconductor device 200 after operation 102. The substrate 210 is provided to form the semiconductor device 200 thereon. The substrate 210 may include a single crystalline semiconductor material such as, but not limited to Si, Ge, SiGe, GaAs, InSb, GaP, GaSb, InAlAs, InGaAs, GaSbP, GaAsSb, and InP. The substrate 210 may include various doping configurations depending on circuit design. For example, different doping profiles, e.g., n-wells, p-wells, may be formed in the substrate 210 in regions designed for different device types, such as n-type field effect transistors (NFET), and p-type field effect transistors (PFET). In some embodiments, the substrate 210 may be a silicon-on-insulator (SOI) substrate including an insulator structure (not shown) for enhancement.

The substrate 210 has a top surface 210f. A channel stack 218 is then formed over the top surface 210f of the substrate 210. The channel stack 218 includes multiple semiconductor layers separated by multiple interposer layers to facilitate formation of nanosheet channels in a multi-gate device, such as nanosheet channel FETs. In some embodiments, the channel stack 218 includes interposer layers 214 interposing between channel layers 216. In some embodiments, the interpose layers 214 and the channel layers 216 may be different semiconductor layers. In other embodiments, the interposer layer 214 may be materials other than semiconductor layers, such as dielectric layers, for example a silicon oxide layer. The interposer layers 214 and channel layers 216 have different oxidation rates and/or etch selectivity. In some embodiments, the top surface 210f of the substrate 210 may have a particular surface orientation to achieve desirable performance, such as (100) orientation or (110) orientation. The orientation of the top surface 210f determines the orientation of the layers in the channel stack 218, and epitaxial features, such as epitaxial source/drain regions formed from the semiconductor channel layers in the channel stack 218.

In later fabrication stages, portions of the channel layers 216 form nanosheet channels in a multi-gate device. Three interposer layers 214 and three channel layers 216 are alternately arranged as illustrated in FIG. 2A as an example. More or less interposer layers 214 and channel layers 216 may be included in the channel stack 218 depending on the desired number of channels in the semiconductor device to be formed. In some embodiments, the number of channel layers 216 is between 1 and 6.

The interposer layers 214 and channel layers 216 may be formed by a molecular beam epitaxy (MBE) process, a metalorganic chemical vapor deposition (MOCVD) process, and/or other suitable epitaxial growth processes. In some embodiments, the channel layers 216 include the same material as the substrate 210. In some embodiments, the interposer layers 214 and channel layers 216 include different materials than the substrate 210. In some embodiments, the interposer layers 214 and channel layers 216 are made of materials having different lattice constants. In some embodiments, the interposer layers 214 include a silicon oxide layer and the channel layers 216 include an epitaxially grown silicon (Si) layer. In some embodiments, the interposer layers 214 include an epitaxially grown silicon germanium (SiGe) layer and the channel layers 216 include an epitaxially grown silicon (Si) layer. Alternatively, in some embodiments, either of the interposer layers 214 and channel layers 216 may include other materials such as Ge, a compound semiconductor such as SiC, GeAs, GaP, InP, InAs, and/or InSb, an alloy semiconductor such as SiGe, GaAsP, AlInAs, AlGaAs, InGaAs, GaInP, and/or GaInAsP, or combinations thereof.

The interposer layers 214 in channel regions may eventually be removed and serve to define a vertical distance between adjacent channels for a subsequently formed multi-gate device. In some embodiments, the thickness of the interposer layer 214 is equal to or greater than the thickness of the channel layer 216. In some embodiments, each interposer layer 214 has a thickness in a range between about 3 nm and about 15 nm. In some embodiments, each channel layer 216 has a thickness in a range between about 3 nm and about 15 nm. In some embodiments, the channel layers 216 in the channel stack 218 are uniform in thickness.

The channel layers 216 may have the same crystalline orientation as the substrate 210 because the interposer layer 214 and the channel layers 216 are alternatively epitaxially grown from the top surface 210f of the substrate 210. As discussed later, the crystalline orientation of the channel layers 216 as crystalline source during subsequent source/drain growth, thereby, affecting crystalline orientation or crystalline structure of the source/drain regions.

The fin structures 220 are formed from the channel stack 218 and a portion of the substrate 210. The fin structures 220 may be formed by patterning a hard mask (not shown) formed on the channel stack 218 and one or more etching processes. Each fin structure 220 has a channel stack 218 formed from the interposer layers 214 and channel layers 216 and a well portion 212 formed from the substrate 210. The fin structures 220 are formed along the X direction.

An isolation layer 222 is formed in the trenches between the fin structures 220. The isolation layer is formed over the substrate 210 to cover the well portion 212 of the fin structures 220. The isolation layer may be formed by a high-density plasma chemical vapor deposition (HDP-CVD), a flowable CVD (FCVD), or other suitable deposition process. In some embodiments, the isolation layer 222 may include silicon oxide, silicon nitride, silicon oxynitride, fluorine-doped silicate glass (FSG), a low-k dielectric, combinations thereof. In some embodiments, the isolation layer is formed to cover the fin structures 220 by a suitable deposition process, such as atomic layer deposition (ALD), and then recess etched using a suitable anisotropic etching process to expose the channel stack 218 of the fin structures 220.

In operation 104, sacrificial gate structures 228 and sidewall spacers 230 are then formed over the fin structures 220, as shown in FIG. 2B. FIG. 2B is schematic cross-sectional view of the semiconductor device 200. A sacrificial gate dielectric layer 224 is deposited over the exposed surfaces of the semiconductor device 200. The sacrificial gate dielectric layer 224 may be formed conformally over the fin structures 220, and the isolation layer 222. In some embodiments, the sacrificial gate dielectric layer 224 may be deposited by a CVD process, a sub-atmospheric CVD (SACVD) process, a FCVD process, an ALD process, a PVD process, or other suitable process. The sacrificial gate dielectric layer 224 may include one or more layers of dielectric material, such as SiO₂, SiN, a high-K dielectric material, and/or other suitable dielectric material.

A sacrificial gate electrode layer 226 is deposited over the sacrificial gate dielectric layer 224. The sacrificial gate electrode layer 226 may be blanket deposited on the over the sacrificial gate dielectric layer 224. The sacrificial gate electrode layer 226 includes silicon such as polycrystalline silicon or amorphous silicon. In some embodiments, the sacrificial gate electrode layer 226 is subjected to a planarization operation. The sacrificial gate electrode layer 226 may be deposited using CVD, including LPCVD and PECVD, PVD, ALD, or other suitable process. Subsequently, a pad layer 225 and a mask layer 227 are formed over the sacrificial gate electrode layer 226. The pad layer 225 may include silicon nitride. The mask layer 227 may include silicon oxide. Next, a patterning operation is performed on the mask layer 227, the pad layer 225, the sacrificial gate electrode layer 226, and the sacrificial gate dielectric layer 224 to form the sacrificial gate structures 228, which cover formed over portions of the fin structures 220 designed to be channel regions.

Gate sidewall spacers 230 are then formed on sidewalls of each sacrificial gate structures 228. After the sacrificial gate structures 228 are formed, the gate sidewall spacers 230 may be formed by a blanket deposition of an insulating material followed by anisotropic etch to remove insulating material from horizontal surfaces. The gate sidewall spacers 230 may have a thickness in a range between about 3 nm and about 8 nm. In some embodiments, the insulating material of the gate sidewall spacers 230 is a silicon nitride-based material, such as SiN, SiON, SiOCN or SiCN and combinations thereof. In some embodiments, the insulating material of the gate sidewall spacers 230 may be a low-k dielectric material, for example a material with a dielectric constant k value in the range of about 4 to about 8. In FIG. 2B, the gate sidewall spacers 230 include two gate sidewall spacer layers 2301, 2302. In other embodiments, the gate sidewall spacers 230 may be formed from less or more layers of dielectric materials.

In operation 106, the fin structures 220 on opposite sides of the sacrificial gate structure 228 are recess etched, forming source/drain recesses 234 between the neighboring sacrificial gate structures 228, as shown in FIG. 2C. FIG. 2C is schematic cross-sectional view of the semiconductor device 200. The interposer layers 214 and the channel layers 216 in the fin structures 220 are etched down on both sides of the sacrificial gate structures 228 using etching operations. In some embodiments, all layers in the channel stack 218 of the fin structures 220 and a portion of the well portions 212 of the fin structures 220 are etched. In some embodiments, suitable dry etching and/or wet etching may be used to remove the interposer layers 214, the channel layers 216, and the substrate 210.

In some embodiments, the source/drain recesses 234 are deep trenches formed below the top surface 210f of the substrate 210. In some embodiments, the source/drain recess 234 below the top surface 210f of the substrate 210 or a sheet bottom to a bottom 234b of the source/drain recesses 234.

In operation 108, inner spacers 232 are formed on exposed ends of the interposer layers 214 under the sacrificial gate structures 228, as shown in FIG. 2D. The interposer layers 214 exposed to the source/drain recesses 234 are first etched horizontally along the X direction to form spacer cavities. In some embodiments, the interposer layers 214 can be selectively etched by using a wet etchant such as, but not limited to, ammonium hydroxide (NH₄OH), tetramethylammonium hydroxide (TMAH), ethylenediamine pyrocatechol (EDP), or potassium hydroxide (KOH) solutions. In some embodiments, the amount of etching of the interposer layer 214 is in a range between about 5 nm and about 10 nm along the X direction.

After forming the spacer cavities at opposite ends of the interposer layers 214, the inner spacers 232 can be formed in the spacer cavities by conformally depositing an insulating layer and then partially removed to form the inner spacer 232 as shown in FIG. 2D. The insulating layer can be formed by ALD or any other suitable method. The subsequent etch process removes most of the insulating layer except inside the cavities, resulting in the inner spacers 232. The inner spacers 232 includes two or more segments, alternately stacked with the channel layers 216.

The inner spacers 232 may be formed from a single layer or multiple layers of dielectric material. In some embodiments, the inner spacers 232 may include one of silicon nitride (SiN) and silicon oxide (SiO₂), SiONC, or a combination thereof. The inner spacer 232 may have a thickness in a range from about 5 nm to about 10 nm along the X direction.

In operation 110, a bottom epitaxial layer 236 is formed in lower portions of the source/drain recesses 234, as shown in FIG. 2E. FIG. 2E is a schematic cross-sectional view of the semiconductor device 200. In some embodiments, the bottom epitaxial layer 236 fills the lower portions of the source/drain recesses 234 to a level below the bottom most channel layer 216L, or the bottom most channel region. In some embodiments, the bottom epitaxial layer 236 fill the source/drain recesses 234 to a level below the bottom most inner spacers 232L. In some embodiment, a front surface 236f may be at a level below the bottom most inner spacers 232L. In some embodiments, the front surface 236f is below the top surface 210f of the substrate 210 and a portion of mesa sidewall 212s is exposed to the source/drain recess 234 after formation of the bottom epitaxial layer 236.

The material and shape of the bottom epitaxial layer 236 may be selected according to achieve one or more purposes. For example, the bottom epitaxial layer 236 may provide crystalline transition from the substrate 210 to the subsequently formed source/drain region with improved adhesion. The bottom epitaxial layer 236 may define a bottom profile and crystalline direction of the subsequently formed source/drain region. In some embodiments, the bottom epitaxial layer 236 may also function as an alignment feature for back side source/drain contacts.

In some embodiments, the bottom epitaxial layer 236 may be formed from a material to have etch selectivity relative to the material of the substrate 210, such as material in the well portion 212 of the fin structure 220. In some embodiments, the bottom epitaxial layer 236 may also have etch selectivity relative to the insulating material in the isolation layer. For example, the bottom epitaxial layer 236 include epitaxially formed silicon.

The bottom epitaxial layer 236 may be formed by any suitable method, such as by CVD, CVD epitaxy, molecular beam epitaxy (MBE), or any suitable deposition technique. In some embodiments, the bottom epitaxial layer 236 are formed from undoped silicon. In some embodiments, the bottom epitaxial layer 236 are formed from undoped SiGe. In some embodiments, the bottom epitaxial layer 236 are formed from undoped SiGe including an atomic concentration of Ge in a range between about 10% and about 100%. Alternatively, the bottom epitaxial layer 236 may include other materials, such as Ge, a compound semiconductor such as SiC, GeAs, GaP, InP, InAs, and/or InSb, an alloy semiconductor such as GaAsP, AlInAs, AlGaAs, InGaAs, GaInP, and/or GaInAsP, or combinations thereof.

In operation 112, a bottom isolation layer 238 is formed over the bottom epitaxial layer 236, ash shown in FIG. 2E. The bottom isolation layer 238 is configured to provide isolation between the well portion 212 of the substrate 210 and subsequently formed source/drain regions above the bottom isolation layer 238. The bottom isolation layer 238 may be formed in any suitable method. In some embodiments, the bottom isolation layer 238 may be formed by first depositing a first material layer over all surfaces, performing a trimming process to remove portions of the first material, such as overhang portions at trench openings and vertical sidewall portions, then performing treatment process is performed to convert the trimmed first material to a dielectric material, then performing anisotropic etch process to remove sidewall portions of the dielectric material, while the bottom portion of the dielectric layer remains to form a bottom isolation layer over the bottom epitaxial layer 236.

In some embodiments, the bottom isolation layer 238 may comprise one or more silicon containing dielectric material, such as silicon oxide (SiO), silicon nitride (SiN), silicon carbide (SiC), silicon-oxy-carbide (SiOC), silicon nitride carbide (SiCN), silicon oxy nitride carbide (SiONC), or a combination. In some embodiment, the bottom isolation layer 238 may comprise one or more metal oxides, such as Al₂O₃, HfO₂, ZrO₂, HfAlOₓ, HfSiOₓ, or other suitable dielectric material.

In some embodiments, the bottom isolation layer 238 may have a thickness in a range between from about 3.5 nm and about 5.0 nm, for example, in a range between about 3.7 nm and 4.3 nm. A thickness less than 3.5 nm may not provide sufficient electrical isolation around the subsequently formed source/drain regions, while a thickness greater than 5.0 nm may cause unnecessary loss of source/drain volume without additional benefit in isolation.

In operation 114, epitaxial source/drain regions 240 are formed in the source/drain recesses 234, as shown in FIG. 2F. FIG. 2F is a schematic cross-sectional view of the semiconductor device 200. In some embodiments, the epitaxial source/drain regions 240 may be a composite semiconductor material includes two or more semiconductor elements. The composite semiconductor material may have a lower melting point lower than other layers in the semiconductor device 200, such as the channel layers 216, the sacrificial gate electrode layer 226, the inner spacers 232, the sidewall spacers 230, thereby may be melted and recrystallized after formation without affect other components of the semiconductor device 200.

In some embodiments, the epitaxial source/drain regions 240 may include one or more layers of epitaxially formed semiconductor layers. In some embodiments, the epitaxial source/drain regions 240 may include a first epitaxial source/drain layer 241 and a bulk epitaxial source/drain layer 243.

In some embodiments, a preclean process may be performed prior to epitaxial growth of the first epitaxial source/drain layer 241. The first epitaxial source/drain layer 241 is formed by an epitaxial growth method using CVD, ALD or molecular beam epitaxy (MBE). The first epitaxial source/drain layer 241 is grown from exposed semiconductor surfaces, i.e., sidewalls 216s of the channel layers 216. The first epitaxial source/drain layer 241 starts as discreet sections from the exposed semiconductor surfaces. For example, the first epitaxial source/drain layer 241 includes multiple sections grown from the sidewall 216s of the channel layers 216.

The first epitaxial source/drain layer 241 is grown to a desired thickness to enable quality crystalline growth in the subsequent bulk epitaxial growth. The first epitaxial source/drain layer 241 may include one or more layers of Si, SiP, SiC and SiCP for NFET or Si, SiGe, Ge for a PFET. For the PFET, p-type dopants, such as boron (B), may also be included in the first epitaxial source/drain layer 241. For NFET, n-type dopants, such as arsenic (As), phosphorous (P), or carbon (C), or combinations thereof, may also be included in the first epitaxial source/drain layer 241.

In some embodiments, the semiconductor device 200 is a p-type device and the first epitaxial source/drain layer 241 includes SiGe with a p-type dopant, such as B or Ga. In some embodiments, the first epitaxial source/drain layer 241 may be a SiGe layer with an atomic concentration of Ge in a range between about 10% and about 30%. In some embodiments, the first epitaxial source/drain layer 241 includes p-type dopants at a concentration between about 1E20 to about 2E21.

In some embodiments, the first epitaxial source/drain layer 241 may be formed by an epitaxial growth method using CVD, ALD or molecular beam epitaxy (MBE). In some embodiments, the epitaxial deposition process may be performed in a temperature range between about 400° C. and about 750° C., for example, between about 520° C. and about 620° C. In some embodiments, the epitaxial deposition process may be performed at a pressure in a range between about 10 torr and about 300 torr, for example, between about 20 torr and about 100 torr. In some embodiments, the epitaxial deposition process may use a precursor, such as H₂SiCₗ₂ (DCS), SiH₄, Si₂H₆, GeH₄, GeCl₄, HCl, Cl₂. In some embodiments, a p-type dopant precursor, such as B₂H₆, BCl₃, and Ga (CH₃)₃, may be used during deposition.

The bulk epitaxial source/drain layer 243 is formed over the first epitaxial source/drain layer 241. The bulk epitaxial source/drain layer 243 fills the source/drain recess 234. The first epitaxial source/drain layer 241 and the bulk epitaxial source/drain layer 243 form epitaxial source/drain regions 240.

The bulk epitaxial source/drain layer 243 is epitaxially grown from the first epitaxial source/drain layer 241. The bulk epitaxial source/drain layer 243 has a higher concentration of dopants than the first epitaxial source/drain layer 241. In some embodiments, composition of the bulk epitaxial source/drain layer 243 is also different from the first epitaxial source/drain layer 241. The bulk epitaxial source/drain layer 243 and the first epitaxial source/drain layer 241 have different crystalline structures. The different crystalline structures are due to different compositions in the bulk epitaxial source/drain layer 243 and the first epitaxial source/drain layer 241. For example, when both of the first epitaxial source/drain layer 241 and the bulk epitaxial source/drain layer 243 include SiGe, the atomic concentration of Ge in the bulk epitaxial source/drain layer 243 is higher than in the first epitaxial source/drain layer 241. Because Ge atoms are larger than Si atoms, lattice dimensions in the crystalline structure of the bulk epitaxial source/drain layer 243 are larger than lattice dimensions in the crystalline structure of the first epitaxial source/drain layer 241. Similarly, the difference in dopant concentrations may also result in crystalline differences.

The bulk epitaxial source/drain layer 243 may include one or more layers of Si, SiP, SiC and SiCP for NFET or Si, SiGe, Ge for a PFET. For the PFET, p-type dopants, such as boron (B), are also included in the bulk epitaxial source/drain layer 243. For NFET, n-type dopants, such as arsenic (As), phosphorous (P), or carbon (C), or combinations thereof, are included in the bulk epitaxial source/drain layer 243.

In some embodiments, the semiconductor device 200 is a p-type device and the bulk epitaxial source/drain layer 243 includes SiGe with a p-type dopant, such as B or Ga. In some embodiments, the bulk epitaxial source/drain layer 243 may be a SiGe layer with an atomic concentration of Ge in a range between about 40% and about 100%. In some embodiments, the bulk epitaxial source/drain layer 243 has a higher Ge composition than the first epitaxial source/drain layer 241. In some embodiments, the bulk epitaxial source/drain layer 243 has a higher dopant concentration than that of the first epitaxial source/drain layer 241. In some embodiments, the bulk epitaxial source/drain layer 243 includes p-type dopants at a concentration between about 1E20 to about 3E21.

In some embodiments, the bulk epitaxial source/drain layer 243 may be formed by an epitaxial growth method using CVD, ALD or molecular beam epitaxy (MBE). In some embodiments, the epitaxial deposition process may be performed in a temperature range between about 400° C. and about 750° C., for example, between about 520° C. and about 620° C. In some embodiments, the epitaxial deposition process may be performed at a pressure in a range between about 10 torr and about 300 torr, for example, between about 20 torr and about 100 torr. In some embodiments, the epitaxial deposition process may use a precursor, such as H₂SiCₗ₂ (DCS), SiH₄, Si₂H₆, GeH₄, GeCl₄, HCl, Cl₂. In some embodiments, a p-type dopant precursor, such as B₂H₆, BCl₃, and Ga (CH₃)₃, may be used during deposition.

As shown in FIG. 2F, the first epitaxial source/drain layer 241 grows from the semiconductor crystalline on the sidewall 216s of the channel layers 216, which are exposed to the source/drain recess 234. The crystalline orientation of the first epitaxial source/drain layer 241 is determined by the sidewall 216s. The bulk epitaxial source/drain layer 243 grows from the crystalline of the epitaxial source/drain layer 241. The first epitaxial source/drain layer 241 and the bulk epitaxial source/drain layer 243 start from discrete segments from the sidewalls 216s and eventually merged. At merger of the discrete segments, crystalline defects 243d, such as crystalline dislocations and mismatches, are generated in the source/drain regions 240. In some embodiments, the crystalline defects 243d may be stacking faults along the (111) orientation. The crystalline defects 243d may form an angle relative to the x-y plane. In some embodiments, the crystalline defects may form an angle about 54.7° relative to the x-y plane.

Even though two epitaxial source/drain layers 241, 243 are shown in the semiconductor device 200, less or more epitaxial source/drain layers may be formed during formation of the source/drain regions 240. In some embodiments, the source/drain regions 240 may be formed from any suitable composite semiconductor materials. For example, the source/drain regions 240 may be formed from SiₓGe_{y}) (0<x<1, 0<y<1), and SiₓGe_{y}P_{z} (0<x<1, 0<y<1, 0<z<1).

In operation 116, a contact etch stop layer (CESL) 242 is deposited over the exposed surfaces, as shown in FIG. 2G. FIG. 2G is a schematic cross-sectional view of the semiconductor device 200. The CESL 242 is formed on the epitaxial source/drain regions 240 and the gate sidewall spacers 230. In some embodiments, the CESL 242 has a thickness in a range between about 1 nm and about 15 nm. The CESL 242 may include Si₃N₄, SiON, SiCN or any other suitable material, and may be formed by CVD, PVD, or ALD.

In operation 118, an interlayer dielectric (ILD) layer 244 is formed over the contract etch stop layer (CESL) 242. The materials for the ILD layer 244 include compounds comprising Si, O, C, and/or H, such as silicon oxide, SiCOH and SiOC. Organic materials, such as polymers, may be used for the ILD layer 244. After the ILD layer 244 is formed, a planarization operation, such as CMP, is performed to expose the sacrificial gate electrode layer 226 for subsequent removal of the sacrificial gate structures 228. The ILD layer 244 protects the epitaxial source/drain regions 240 during the removal of the sacrificial gate structures 228.

In operation 120, a high temperature treatment is performed to melt the source/drain regions 240 and induce recrystallization, as shown in FIGS. 2H and 2I. In operation 120, the high temperature treatment is performed to melt the source/drain regions 240 without affecting other layers or components. As shown in FIG. 2H, a heat beam 233 is applied to the semiconductor device 200. The heat beam 233 penetrates through the ILD layer 244 and the CESL 242 above the source/drain regions 240 and melts the source/drain regions 240. After removal of the heat beam 233, the melted source/drain regions 240 recrystallize with the crystalline defects 243d removed, as shown in FIG. 2I. In some embodiments, the crystalline orientation is uniform in entire recrystallized source/drain regions 240′. With the defects 243d substantially removed, the recrystallized source/drain regions 240′ have relaxed strain leading to lowered resistance and improved dopant activation. In some embodiments, the recrystallized source/drain regions 240′ demonstrate 3 times to 5 times higher dopant activation compared to untreated epitaxial source/drain regions 240.

In some embodiments, traces of crystalline defects, such as dislocations, may remain in the source/drain regions after the annealing process. However, distribution of the remaining defects may be higher in the bottom portion of the source/drain regions 240 than in the upper portion of the source/drain region 240. Because the heat source is delivered from top to bottom during the annealing process, the top portion of the source/drain regions 240 may be benefit more from the annealing process than the bottom portion of the source/drain regions 240. In some embodiments, the remaining crystalline defects may be located at the bottom portion of the source/drain regions 240 adjacent to the bottom isolation layer 238.

As discussed above, the source/drain regions 240, i.e. the first epitaxial source/drain layer 241 and the bulk epitaxial source/drain layer 243, are formed of composite semiconductor materials. Melting points of the composite semiconductor materials may be selected to allow complete melting of the source/drain regions 240 during the high temperature treatment without melting other material layers.

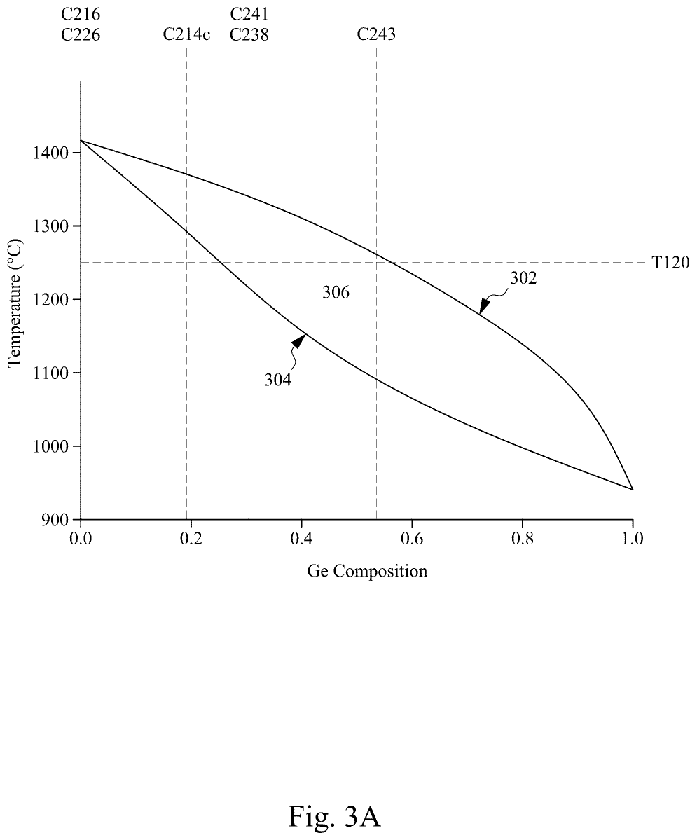

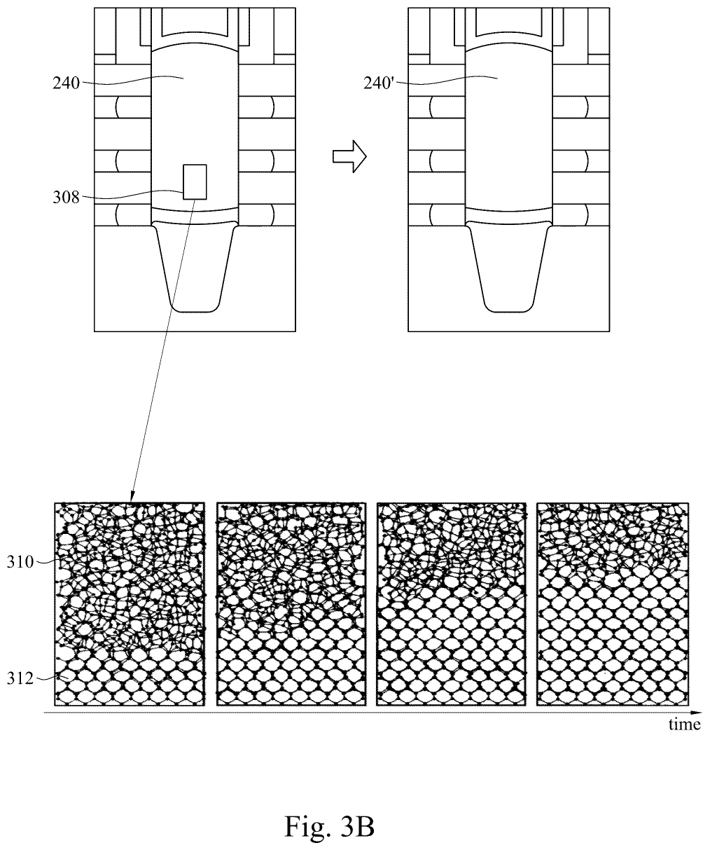

FIG. 3A is an exemplary phase diagram of silicon-germanium composite. The x-axis indicates atomic ratio of germanium in the silicon-germanium composite. The y-axis indicates temperature. Curve 302 is liquidus. The SiGe compositions in area above the curve 302 is entirely liquid. Curve 304 is solidus. The SiGe compositions below the curve at entirely solid. Area 306 between curves 302 and 304 is the melton area, the SiGe compositions in the area 306 are part solid and part liquid. Vertical height of the molten aera 306 is controlled by composition of the SiGe material. For pure silicon and pure germanium, solidus and liquidus overlap and the vertical height of the molten area 306 is zero. Pure silicon has a melting point about 1414° C. Pure germanium has a melting point about 937° C. In some embodiments, when the source/drain regions 240 are formed of SiGe, the high temperature treatment heat the SiGe materials in the source/drain region 240 to above the solidus while other semiconductor materials, such as the channel layers 216 and the sacrificial gate electrode layer 226, remain in solid phase.

In FIG. 3A, vertical lines C216/C226, C241, C243 correspond to compositions of the channel layers 216/the sacrificial gate electrode layer 226, the first epitaxial source/drain layer 241 and the bulk epitaxial source/drain layer 243 respectively. Horizontal line T120 corresponds to a treatment temperature during the high temperature treatment in operation 120. As shown in FIG. 3A, at the treatment temperature T120, both the first epitaxial source/drain layer 241 and the bulk epitaxial source/drain layer 243 are in the molten area 306 while the channel layers 216 and the sacrificial gate electrode layer 226 are in solid state.

In some embodiments, a predetermined amount of energy is dispatched to the semiconductor device 200 to melt the source/drain regions 240. In some embodiments, the predetermined amount of the energy is selected to position the source/drain regions 240, i.e. the first epitaxial source/drain layer 241 and the bulk epitaxial source/drain layer 243, in molten state while other materials, such as the channel layers 216 and the sacrificial gate electrode layer 226, remain in solid state.

In some embodiments, the heat beam 233 is dispatched toward the semiconductor device 200 to heat the semiconductor device 200 to a predetermined temperature to melt the materials in the source/drain region 240. The predetermined temperature may be selected according to the composition of the source/drain regions 240. In some embodiments, the predetermined temperature is in a range between about 1000° C. and about 1400° C.

Recrystallization in the melton source/drain regions 240 starts at the lowest temperature spots. Because energy of the heat beam 233 penetrates from top down, temperature of the semiconductor device 200 decreases from the top surface along the z-axis. Therefore, recrystallization in the melted source/drain regions 240 starts from the bottom to top. FIG. 3B schematically demonstrates recrystallization sequence of an area 308 in the source/drain regions 240. As shown in FIG. 3B, the source/drain region 240 recrystallizes in a bottom up manner. After the heat beam 233 is removed, a recrystallized region 312 grows from into molten region 310 from bottom up along the z-axis.

Recrystallized source/drain regions 240′ do not include crystalline defects, for example, recrystallized source/drain regions 240′ do not include any stacking faults, such as stacking faults along the (111) orientation. In some embodiments, the recrystallized source/drain regions 240′ have the same crystalline orientation as the substrate 210. For example, when the substrate 210 has a (100) crystal orientation, the entire recrystallized source/drain region 240′ has a (100) crystal orientation. In some embodiments, the recrystallized source/drain regions 240′ have a uniform SiGe composition. For example, the recrystallized source/drain regions 240′ may have a Ge concentration greater than the first epitaxial source/drain layer 241 and lower than the bulk epitaxial source/drain layer 243. In some embodiments, the recrystallized source/drain regions 240′ have a Ge concentration in range between about 35% and about 95%.

The high temperature treatment may utilize any suitable electromagnetic energy, such as an optical radiation source, an electron beam source, or a microwave energy source. In some embodiments, the high temperature treatment high temperature treatment is performed by an optical radiation source using a laser. The heat beams 233 may be delivered by scanning a laser beam from an energy source across the exposed surface of the epitaxial source/drain regions 240. In some embodiments, the laser beam may be applied to entire semiconductor device 200 or portions of the semiconductor device 200. In any case, the lase beam may be delivered to the target area while the semiconductor device 200 is translated, or scanned, relative to the energy (or vice versa) delivered to the target area. For example, the laser beam may heat a first portion (e.g., exposed surface of the epitaxial source/drain regions) for a first device, then the semiconductor device 200 and/or laser beam may be moved, and the laser beam may heat a second portion (e.g., exposed surface of the epitaxial source/drain regions 240) of the semiconductor device 200.

The energy source may be any type of laser, such as CO₂ laser, Nd-YAG laser, Ti:sapphire laser, fiber laser, III-V semiconduction laser, Argon ion laser, or XeCl excimer laser to heat up the semiconductor device 200 to a temperature near the SiGe melting point without melting Si substrate. The laser beam may have a constant energy flux. In some embodiments, the laser beam may have a wavelength in a range from about 200 nm to about 20 micrometers, such as from about 280 nm to about 1200 nm, for example about 300 nm to about 1000 nm, and the laser beam may deliver an energy density that is capable of melting the epitaxial source/drain regions 240. In some examples, the energy density may be delivered in a range from about 0.01 J/cm to about 5 J/cm. The dwell time of the laser beam may be in a range from about 1 nanosecond to about 1000 nanoseconds, such as about 10 nanoseconds to about 500 nanoseconds, for example about 20 nanoseconds to about 200 nanoseconds.

In some embodiments, a rapid thermal anneal (RTA) may be used in the high temperature treatment. The RTA process may recrystallize or repair the lattice structure of the source/drain regions 240.

In some embodiments, a millisecond annealing (MSA) process may be used in the high temperature treatment. The MSA process may utilize a laser anneal or flash anneal process to achieve the annealing times in the range of milliseconds. The MSA process offers lower thermal budget and thus can be used to further control or modify the dopant profiles, thereby enhancing the dopant activation. The MSA may be added in any order to the annealing processes discussed above.

In operation 122, replacement gate structures 250 are formed in place of the sacrificial gate structures 228, as shown in FIG. 2I. FIG. 2I is a schematic cross-sectional view of the semiconductor device 200. The sacrificial gate structures 228 are first removed. Particularly, the sacrificial gate electrode layer 226 and the sacrificial gate dielectric layer 224 are removed sequentially to expose the channel portion. The interposer layers 214 and the channel layers 216 are exposed. The interposer layers 214 are then selectively removed using an etchant with a higher etch rate with respect to the interposer layers 214 than the etch rate with respect to the channel layers 216. After the interposer layers 214 are removed, the channel layers 216 are exposed resulting in a semiconductor channel region including the channel layers 216 in connection to the recrystallized epitaxial source/drain regions 240′.

The replacement gate structures 250 are then formed around the channel region. A gate dielectric layer 246 is formed around each of the channel layers 216 and a gate electrode layer 248 is formed on the gate dielectric layer 246. The gate dielectric layer 246 and the gate electrode layer 248 may be referred to as a replacement gate structure 250.

The gate dielectric layer 246 may be formed by CVD, ALD or any suitable method. In one embodiment, the gate dielectric layer 246 is formed using a highly conformal deposition process such as ALD in order to ensure the formation of a gate dielectric layer 246 having a uniform thickness around each of the channel layers 216. In some embodiments, the thickness of the gate dielectric layer 246 is in a range between about 1 nm and about 6 nm.

The gate dielectric layer 246 includes one or more layers of a dielectric material, such as silicon oxide, silicon nitride, or high-k dielectric material, other suitable dielectric material, and/or combinations thereof. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof. In some embodiments, the gate dielectric layer 246 has a higher k-value than that of the gate sidewall spacers 230. In some embodiments, the gate dielectric layer 246 includes a high-K dielectric material having a k-value greater than about 9.0. In some embodiments, the thickness of the high-k dielectric material in the gate dielectric layer 246 is less than about 3 nm. In some embodiment, the thickness of high-K dielectric material in the gate dielectric layer 246 is thinner than that of the gate sidewall spacers 230. In some embodiments, an interfacial layer (not shown) is formed between the second semiconductor layer 216 and the gate dielectric layer 246. In some embodiments, one or more work function adjustment layers (not shown) are interposed between the gate dielectric layer 246 and the gate electrode layer 248.

The gate electrode layer 248 is formed on the gate dielectric layer 246 to surround each of the channel layer 216 and the gate dielectric layer 246. The gate electrode layer 248 includes one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or combinations thereof. The gate electrode layer 248 may be formed by CVD, ALD, electro-plating, or other suitable method.

In operation 124, source/drain contacts 254 and gate contacts 260 are formed, as shown in FIG. 2k. In some embodiments, a second ILD layer 258 is formed over the semiconductor device. Conductive features, such as the source/drain contact 254 and gate contacts 260 are formed through the second ILD layer 258. Prior to forming the source/drain contacts 254, contact openings are formed through the second ILD layer 258, the ILD layer 244, the CESL 242 to expose the source/drain regions 240′. Suitable photolithographic and etching techniques are used to form the contact openings through various layers.

After the formation of the contact openings, a silicide layer 252 is selectively formed over the exposed surfaces of the epitaxial source/drain regions 240′. The silicide layer 252 conductively couples the epitaxial source/drain regions 240′ to the subsequently formed the source/drain contacts 254. The silicide layer 252 may be formed by depositing a metal source layer to cover the epitaxial source/drain regions 240′ and performing a rapid thermal annealing process. In some embodiments, the metal source layer includes a metal layer selected from W, Co, Ni, Ti, Mo, and Ta, or a metal nitride layer selected from tungsten nitride, cobalt nitride, nickel nitride, titanium nitride, molybdenum nitride, and tantalum nitride. After the formation of the metal source layer, a rapid thermal anneal process is performed, for example, a rapid anneal at about 800° C. During the rapid anneal process, the portion of the metal source layer over the epitaxial source/drain regions 240′ reacts with silicon in the epitaxial source/drain regions 240′ to form the silicide layer 252. Unreacted portion of the metal source layer is then removed. In some embodiments, the silicide layer 252 includes a compound of metal in the metal source and the source/drain material, such as MSi and MiSiGe, M stands for a metal, such as W, Co, Ni, Ti, Mo, and Ta. In some embodiments, the silicide layer 252 may have different compositions for n-type devices and p-type devices. For example, the silicide layer 252 for n-type devices may include one or more of WSi, CoSi, NiSi, TiSi, MoSi, and TaSi. The silicide layer 252 for p-type devices may include one or more of WSiGe, CoSiGe, NiSiGe, TiSiGe, MoSiGe, and TaSiGe.

After the silicide layer 252 is formed, the source/drain contacts 254 are formed in the contact openings by CVD, ALD, electro-plating, or other suitable method. The source/drain contacts 254 may include one or more of Co, Ni, W, Ti, Ta, Cu, Al, TiN and TaN. In some embodiments, a barrier layer (not shown) may be formed on sidewalls of the contact holes prior to forming the source/drain contacts 254.

In some embodiments, contact openings may be formed through the second ILD layer 258 to expose a portion of the gate electrode 248. The gate contacts 260 are then formed by depositing a conductive material, such as one or more of Co, Ni, W, Ti, Ta, Cu, Al, TiN and TaN. In some embodiments, the gate contacts 260 may be formed at the same time with the source/drain contacts 254.

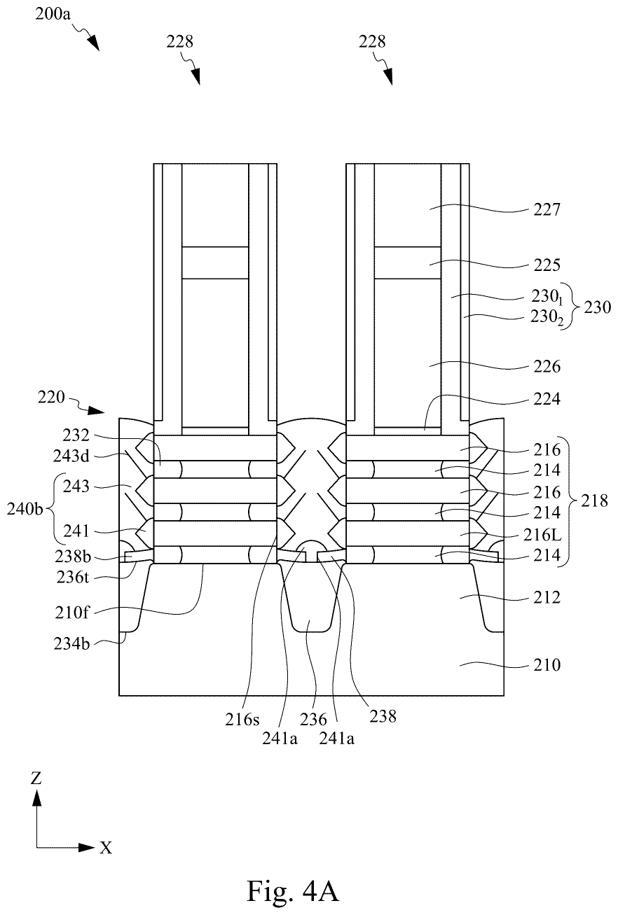

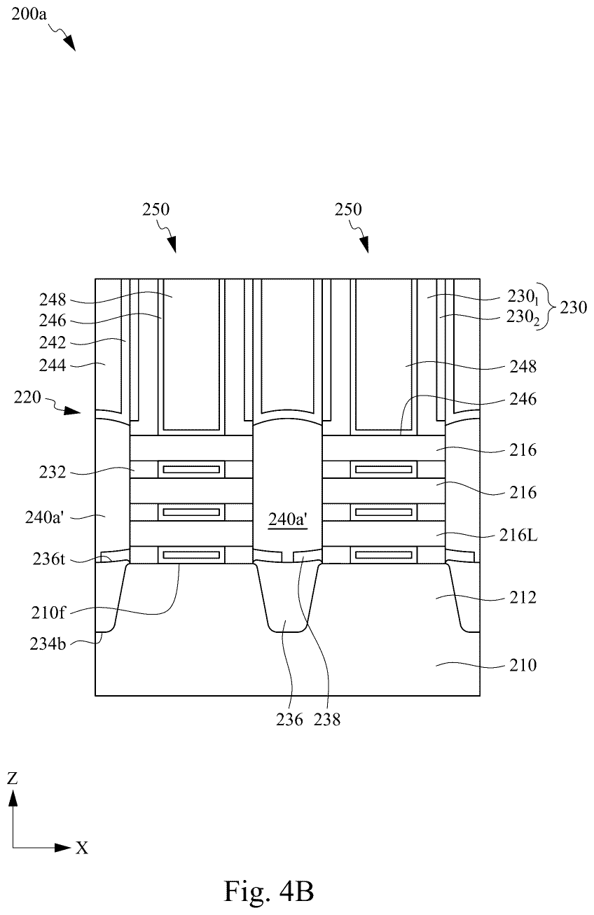

FIGS. 4A and 4B schematically illustrate a semiconductor device 200a according to another embodiment of the present disclosure. The semiconductor device 200a is similar to the semiconductor device 200 except that the bottom isolation layer 238 includes one or more openings 238H. The openings 238H may be formed by a suitable deposition/etch process in operation 112.

The one or more openings 238H expose the bottom epitaxial layer 236 to the source/drain recesses 234 during formation of source/drain regions. FIG. 4A is schematic cross-sectional view of the semiconductor device 200a after operation 114. The semiconductor device 200a includes epitaxial source/drain regions 240a, which includes a first epitaxial layer 241a grown from the top surface 236t of the bottom epitaxial layer 236.

FIG. 4B schematically illustrates the semiconductor device 200a after the high temperature treatment and recrystallization. As shown in FIG. 4B, recrystallized source/drain region 240a′ starts from a semiconductor surface, i.e. the top surface 236t of the bottom epitaxial layer 236. By recrystallizing from a semiconductor surface through the openings 238H in the bottom isolation layer 238, the recrystallized epitaxial source/drain regions 240a is void of any defects generated from the dielectric surface while still retain the solation benefit of the bottom isolation layer 238.

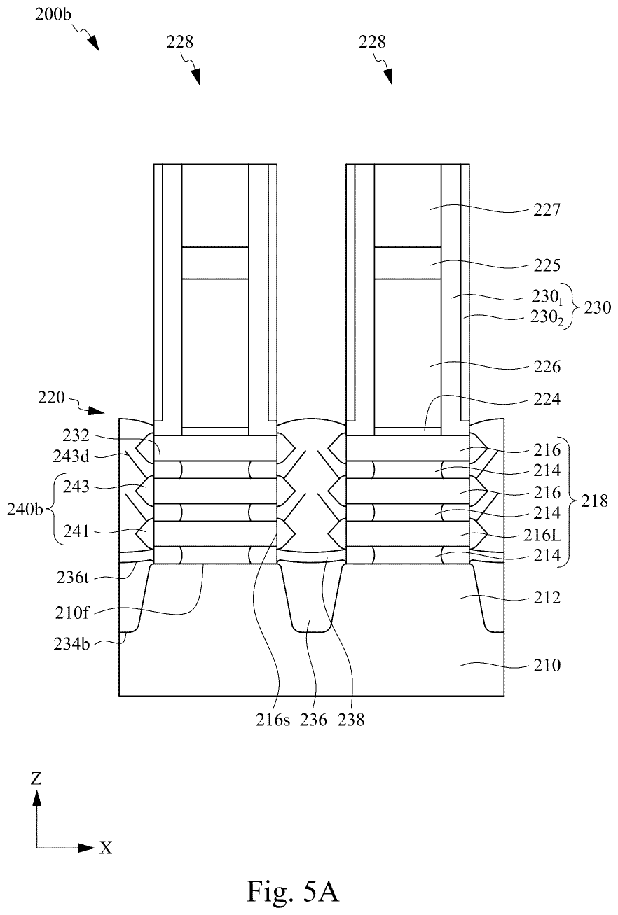

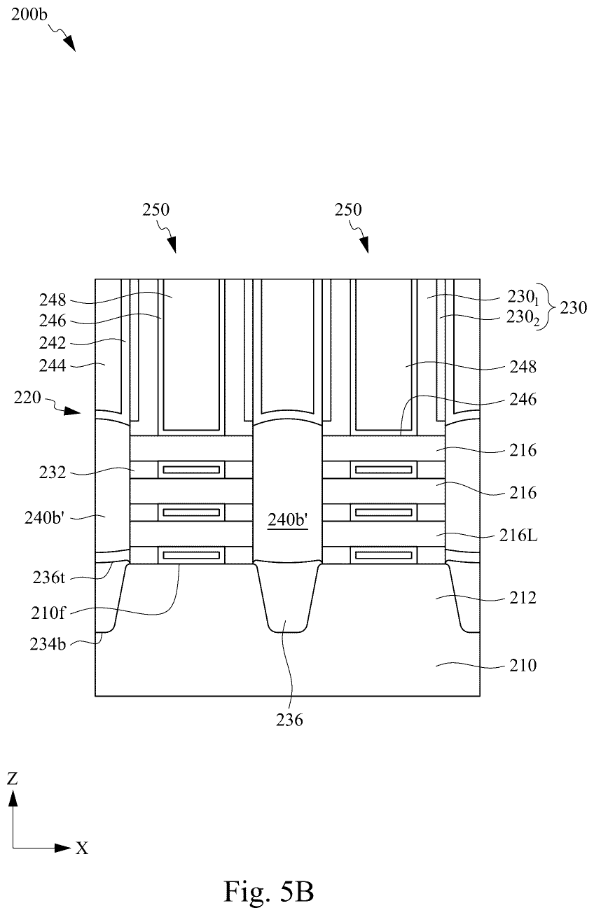

FIGS. 5A and 5B schematically illustrate a semiconductor device 200b according to another embodiment of the present disclosure. The semiconductor device 200b is similar to the semiconductor device 200 except that the bottom isolation layer 238 is replaced with an undoped semiconductor layer 238b. In some embodiments, the undoped semiconductor layer 238b may include a SiGe layer with a Ge composition in a range between about 10% and about 40%. In some embodiments, composition of the undoped semiconductor layer 238b may be selected to allow the undoped semiconductor layer 238b to be in the molten state during the subsequent high temperature treatment.

FIG. 5A is schematic cross-sectional view of the semiconductor device 200a after operation 114. The semiconductor device 200b includes epitaxial source/drain regions 240b formed over the undoped semiconductor layer 238b.

FIG. 5B schematically illustrates the semiconductor device 200b after the high temperature treatment and recrystallization. As shown in FIG. 5B, recrystallized source/drain region 240b′ starts from a semiconductor surface, i.e. the top surface 236t of the bottom epitaxial layer 236. By recrystallizing from a semiconductor surface, the recrystallized epitaxial source/drain regions 240a is void of any defects generated from the dielectric surface, i.e. a top surface of the bottom isolation layer 238.

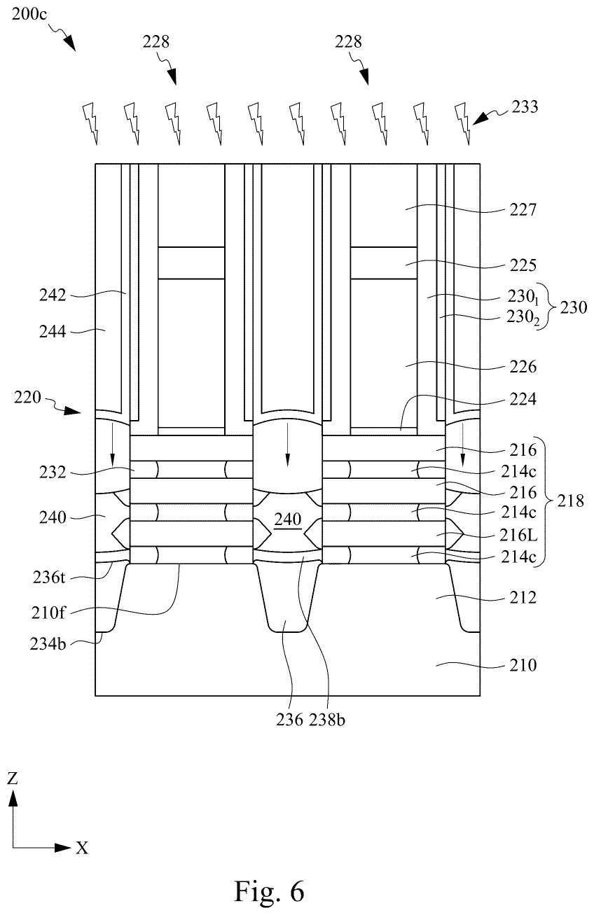

FIG. 6 schematically illustrates a semiconductor device 200c according to another embodiment of the present disclosure. The semiconductor device 200c is similar to the semiconductor device 200 except that the channel layers 216 is separated by interposer layers 214c. The interposer layers 214c are semiconductor layers. In some embodiments, the interposer layer 214c may be a SiGe layer with a Ge composition in a range between about 10% and about 40%. In some embodiments, composition of the interposer layer 214c may be selected to allow the interposer layer 241c to remain in solid state, therefore, avoid diffusion of Ge into the channel layers 216.

FIG. 6 is schematic cross-sectional view of the semiconductor device 200c during the high temperature treatment. As shown in FIG. 6, the interposer layers 214c remain in solid state while the epitaxial source/drain regions 240 melt. The sacrificial gate electrode layer 226, which is disposed over the channel stack 218, has a higher thermal coefficient than the IDL layer 244, which is disposed over the epitaxial source/drain regions 240. The sacrificial gate electrode layer 226 shields the semiconductor interposer layer 214c during the high temperature treatment.

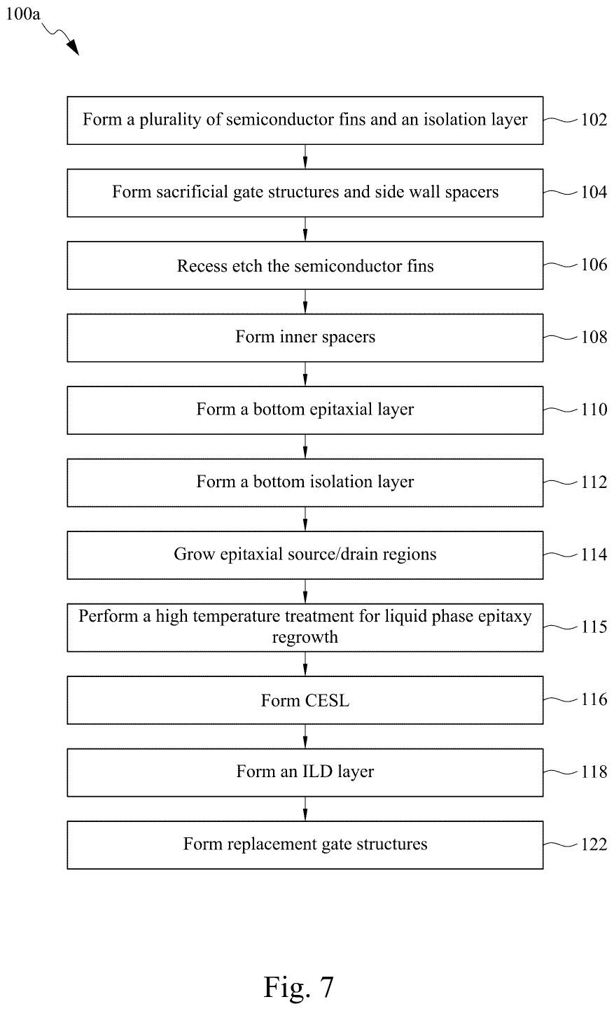

FIG. 7 is a method 100a of forming a semiconductor device according to embodiments of the present disclosure. The method 100a is similar to the method 100 except that a high temperature treatment is performed immediately after formation of the source/drain regions 240.

The method 100a includes an operation 115, which includes a high temperature treatment after formation of the epitaxial source/drain regions 240 operation 114 and prior to deposition of CESL 242.

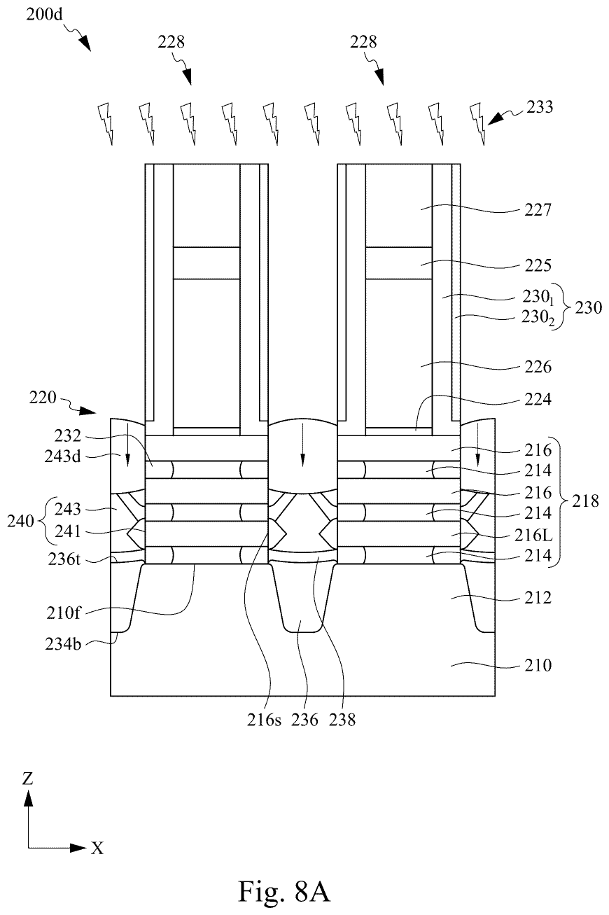

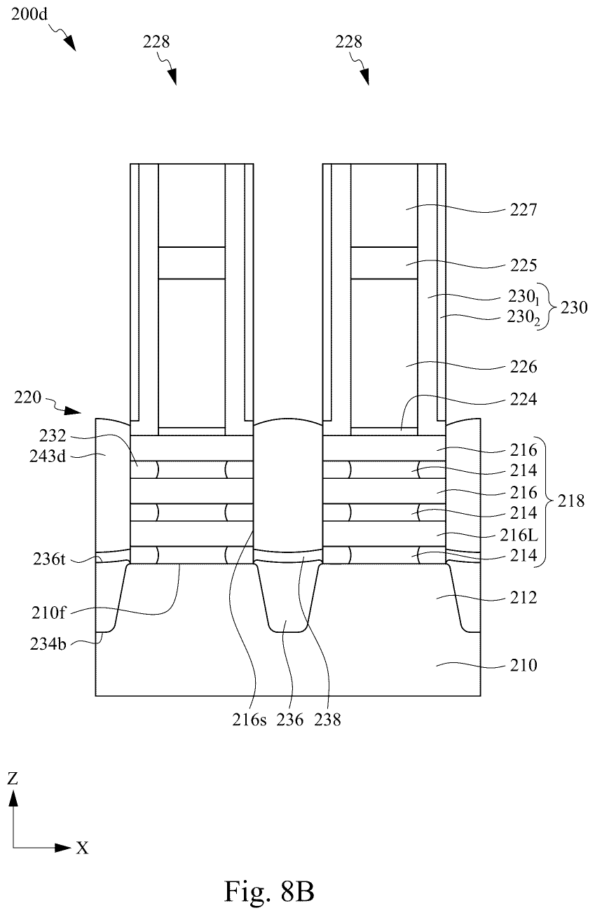

The operation 115 may be similar to the operation 120 in the method 100. FIG. 8A schematically illustrates a semiconductor device 200d during operation 115. FIG. 8B is schematically illustrates the semiconductor device 200d after recrystallization. While performing high temperature treatment after deposition of the CESL 242 and the ILD layer 244 may prevent oxidation of the epitaxial source/drain regions 240, performing the high temperature treatment before deposition of the CESL 242 and ILD layer 244 may improve efficiency of the high temperature treatment, thus, reducing effect formation between the interface of the recrystallized epitaxial source/drain regions 240 and the bottom isolation layer 238.

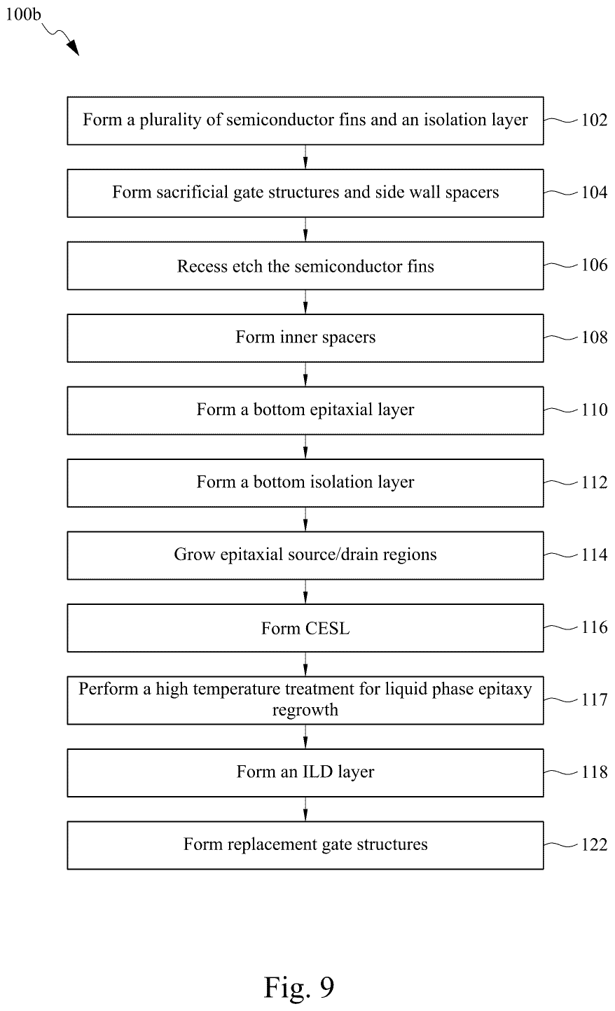

FIG. 9 is a method 100b of forming a semiconductor device according to embodiments of the present disclosure. The method 100b is similar to the method 100 except that a high temperature treatment is performed immediately after formation of the deposition of the CSEL 242.

The method 100b includes an operation 117, which includes a high temperature treatment after deposition of the CESL 242 and prior to deposition of the ILD layer 244.

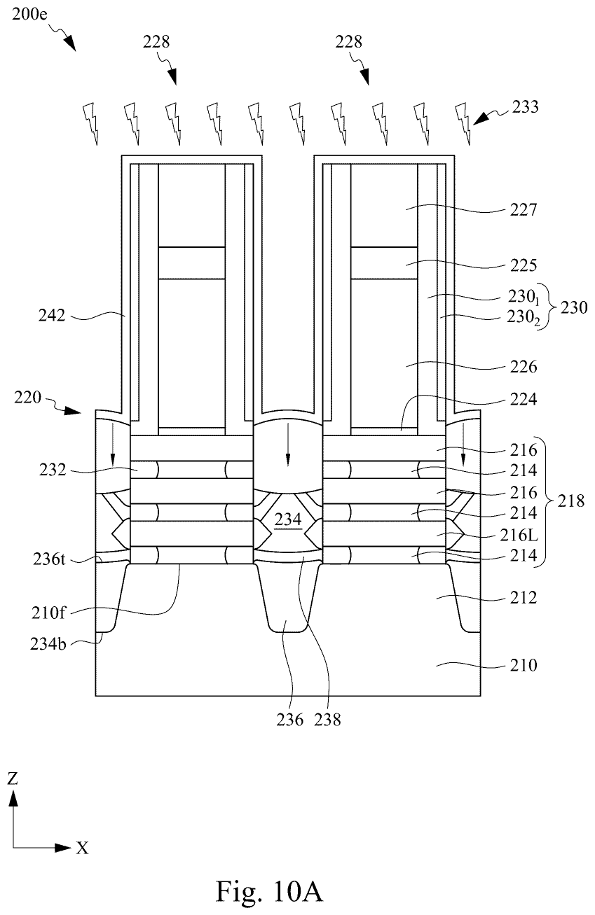

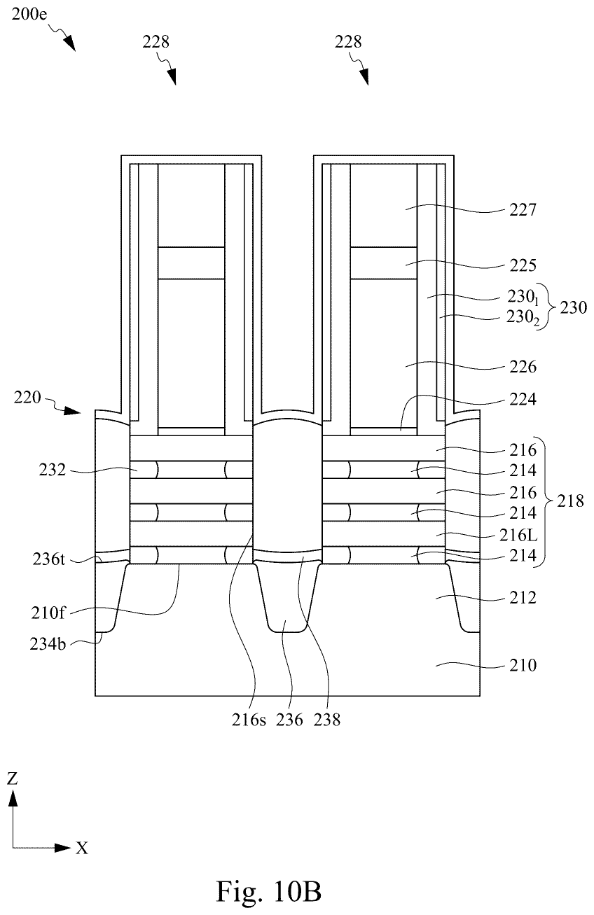

The operation 117 may be similar to the operation 120 in the method 100. FIG. 10A schematically illustrates a semiconductor device 200e during operation 117. FIG. 10B is schematically illustrates the semiconductor device 200e after recrystallization. While performing high temperature treatment after deposition of the CESL 242 and prior to deposition of the ILD layer 244 may simultaneously prevent oxidation of the epitaxial source/drain regions 240 and improve efficiency of the high temperature treatment.

The methods 100a and 100b may be used to fabricate the semiconductor devices 200a, 200b, 200c as well.

Various embodiments or examples described herein offer multiple advantages over the state-of-art technology. Embodiments of the present disclosure provide a method including high temperature treatment of source/drain regions to form recrystallized source/drain regions. Embodiments of the present disclosure reduce strain in the source/drain regions, boot dopant activation, improve Iₒₙ-I_{off}, reduce resistance between source/drain regions and the channel layer.

It will be understood that not all advantages have been necessarily discussed herein, no particular advantage is required for all embodiments or examples, and other embodiments or examples may offer different advantages.

Some embodiments of the present disclosure provide a method comprising forming a fin structure on a top surface of a semiconductor substrate, wherein the semiconductor substrate comprises a first semiconductor element; forming a recess through the fin structure and into the semiconductor substrate; growing an epitaxial source/drain region in the recess, wherein the epitaxial source/drain region comprises the first semiconductor element and a second semiconductor element; and heating the epitaxial source/drain region to a molten state while the semiconductor substrate and allowing the epitaxial source/drain region to recrystallized.

Some embodiments of the present disclosure provide a method comprising forming a fin structure on a top surface of a semiconductor substrate, wherein the fin structure comprises interposer layers and channel layers alternately arranged; forming a recess through the fin structure and into the semiconductor substrate; selectively etching back the interposer layers to form inner spacers between the channel layers; growing a bottom epitaxial layer in the recess; forming a bottom isolation layer over the bottom epitaxial layer; growing an epitaxial source/drain region from the channel layers over the bottom isolation layer; depositing a contact etch stop layer over the epitaxial source/drain region; depositing an interlayer dielectric layer over the contact etch stop layer; and heating the epitaxial source/drain region to a molten state and allowing the epitaxial source/drain region to recrystallize.

Some embodiments of the present disclosure provide a semiconductor device. The semiconductor device comprises a substrate comprising a first semiconductor element; two or more channel layers vertically stacked above a top surface of the substrate, wherein the two or more channel layers comprise the first semiconductor element, and the top surface of the substrate has a first crystalline orientation; two or more inner spacers disposed alternately stacked with the two or more channel layers; and a source/drain region connected to the two or more channel layers, wherein the source/drain region comprises the first semiconductor element and a second semiconductor element, the source/drain region has a uniform crystalline along the first crystalline orientation

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method comprising:
forming a fin structure on a top surface of a semiconductor substrate, wherein the semiconductor substrate comprises a first semiconductor element;
forming a recess through the fin structure and into the semiconductor substrate;
growing an epitaxial source/drain region in the recess, wherein the epitaxial source/drain region comprises the first semiconductor element and a second semiconductor element; and
heating the epitaxial source/drain region to a molten state while the semiconductor substrate and allowing the epitaxial source/drain region to recrystallized.

2. The method of claim 1, forming the fin structure comprising:
forming a channel stack on the semiconductor substrate, wherein the channel stack comprises two or more interposer layer and two or more channel layers alternately arranged; and
patterning the channel stack and the semiconductor substrate to form the fin structure.

3. The method of claim 2, wherein the one or more channel layers comprise the first semiconductor element and the interposer layer comprises a dielectric material.

4. The method of claim 2, wherein the one or more channel layers comprise the first semiconductor element and the interposer layer comprises a semiconductor composite of the first semiconductor element and the second semiconductor element.

5. The method of claim 2, further comprising: forming a bottom isolation layer in the recess prior to growing the epitaxial source/drain region.

6. The method of claim 5, wherein the bottom isolation layer comprises a dielectric layer.

7. The method of claim 6, wherein the bottom isolation layer comprises an epitaxial layer comprises the first semiconductor element and the second semiconductor element, and the bottom isolation layer recrystallize with the epitaxial source/drain region.

8. The method of claim 1, wherein the first semiconductor element is Si and the second semiconductor element is Ge.

9. The method of claim 8, wherein heating the epitaxial source/drain region comprises heating the epitaxial source/drain region to a temperature range between about 1000° C. and about 1400° C.

10. A method comprising:
forming a fin structure on a top surface of a semiconductor substrate, wherein the fin structure comprises interposer layers and channel layers alternately arranged;
forming a recess through the fin structure and into the semiconductor substrate;
selectively etching back the interposer layers to form inner spacers between the channel layers;
growing a bottom epitaxial layer in the recess;
forming a bottom isolation layer over the bottom epitaxial layer;
growing an epitaxial source/drain region from the channel layers over the bottom isolation layer;
depositing a contact etch stop layer over the epitaxial source/drain region;
depositing an interlayer dielectric layer over the contact etch stop layer; and
heating the epitaxial source/drain region to a molten state and allowing the epitaxial source/drain region to recrystallize.

11. The method of claim 10, wherein heating the epitaxial source/drain region is performed after depositing the interlayer dielectric layer.

12. The method of claim 10, wherein heating the epitaxial source/drain region is performed prior to depositing the interlayer dielectric layer.

13. The method of claim 12, wherein heating the epitaxial source/drain region is performed after depositing the contact etch stop layer and prior to depositing the interlayer dielectric layer.

14. The method of claim 12, wherein heating the epitaxial source/drain region is performed prior to depositing the contact etch stop layer.

15. The method of claim 10, wherein growing the epitaxial source/drain region comprises:
growing a first epitaxial source/drain layer from the channel layers; and
growing a bulk epitaxial source/drain layer from the first epitaxial source/drain layer, wherein the first epitaxial source/drain layer comprises a first SiGe material, and bulk source/drain layer comprises a second SiGe material, and the second SiGe material has a higher Ge concentration than the first SiGe material.

16. A semiconductor device, comprising:
a substrate comprising a first semiconductor element;
two or more channel layers vertically stacked above a top surface of the substrate, wherein the two or more channel layers comprise the first semiconductor element, and the top surface of the substrate has a first crystalline orientation;
two or more inner spacers disposed alternately stacked with the two or more channel layers; and
a source/drain region connected to the two or more channel layers, wherein the source/drain region comprises the first semiconductor element and a second semiconductor element, the source/drain region has a uniform crystalline along the first crystalline orientation.

17. The semiconductor device of claim 16, wherein the first semiconductor element is Si and the second semiconductor element is Ge.

18. The semiconductor device of claim 17, further comprises a bottom isolation layer disposed under the source/drain region.

19. The semiconductor device of claim 18, wherein the bottom isolation layer includes an opening, and the source/drain region extends through the opening of the bottom isolation layer.

20. The semiconductor device of claim 18, further comprising:
a gate structure disposed around the two or more channel layers; and
inner spacers disposed between the gate structures and the source/drain regions.
